(19) United States
(12) Patent Application Publication
(10) Pub. No.: US 2025/0130507 A1
(43) Pub. Date: Apr. 24, 2025

(54) METHOD FOR PRODUCING OPTICAL ELEMENT

(71) Applicant: Mitsubishi Chemical Corporation, Tokyo (JP)

(72) Inventors: Ken SATO, Tokyo (JP); Asato TANAKA, Tokyo (JP); Kazuma INOUE, Tokyo (JP)

(73) Assignee: Mitsubishi Chemical Corporation, Tokyo (JP)

(21) Appl. No.: 18/999,537

(22) Filed: Dec. 23, 2024

Related U.S. Application Data
(63) Continuation of application No. PCT/JP2023/024168, filed on Jun. 29, 2023.

(30) Foreign Application Priority Data
Jun. 30, 2022 (JP) 2022-106251

(51) Int. Cl. G03F 7/00; G03H 1/02

(52) U.S. Cl. CPC G03F 7/70408; G03F 7/0005; G03F 7/70466; G03H 1/02; G03H 2001/0264; G03H 2260/12

(57) ABSTRACT

A method for producing an optical element, wherein a hologram recording medium having a recording layer containing a polymerizable compound and a photopolymerization initiator is subjected to multiple recording exposure of a hologram under conditions where average exposure intensity based on the following formula (1) is 6 mW/cm² or more.

$$Average exposure intensity = \frac{{\sum }_{i = 1}^{m} ( {ET}_{i} \times {EPW}_{i} )}{{\sum }_{i = 1}^{m} ( {ET}_{i} + {EIT}_{i - 1} )} \qquad ( 1 )$$

(In the formula (1), ETᵢ is a single exposure time, which indicates exposure time (seconds) per multiple recording exposure. EPWᵢ is exposure light intensity, which indicates total light intensity (mW/cm²) of reference light and object light. EITᵢ₋₁ is exposure interval time, which indicates time (seconds) between one recording exposure and another recording exposure in the multiple recording exposure. m is a natural number indicating a total number of multiplexes. With the proviso that when i=1, EITᵢ₋₁ is treated as zero.)

### CROSS-REFERENCE TO RELATED APPLICATIONS

The present application is a continuation of International Patent Application PCT/JP2023/024168, filed Jun. 29, 2023, which is based on and claims the benefit of priority to Japanese Application No. 2022-106251, filed Jun. 30, 2022. The entire contents of these applications are incorporated herein by reference.

The present invention relates to a method for producing an optical element by performing multiple recording exposure of a hologram on a hologram recording medium.

### BACKGROUND ART

A holographic recording medium, which has been attracting attention in recent years, is a recording medium that utilizes light interference and diffraction phenomena. A hologram is a recording method in which an interference pattern created by interference fringes of two lights (referred to as recording lights) called a reference light and an object light (also referred to as information light or signal light) is three-dimensionally recorded inside a recording medium. A holographic recording medium contains a photosensitive material in its recording layer. In a holographic recording medium, interference patterns are recorded by chemically changing the photosensitive material in accordance with the interference pattern and locally changing its optical properties.

A holographic recording medium has been developed for memory applications. As another use of the holographic recording medium, studies are being conducted to apply it to optical element such as light guide plate for AR glass, and the like. In the case of AR glass (AR glasses) applications, the holographic recorded optical element used in the light guide plate is required to have a wide viewing angle, high diffraction efficiency for light in the visible region, and high transparency of the medium.

A holographic recording medium can be classified ed into several types depending on what kind of optical properties are changed. It has been considered that a volume type hologram recording medium, which performs recording by creating a refractive index difference within a recording layer having a thickness more than a certain thickness, is advantageous for applications to a light guide plate of AR glass, because it can save space and achieve high diffraction efficiency and wavelength selectivity.

An example of a volume type holographic recording medium is a write-once type which does not require wet processing or bleaching. A composition of a recording layer thereof is generally one in which a photoactive compound is compatibilized in a matrix resin. For example, it is known to use a photopolymer as a recording layer, in which a matrix resin is combined with a photoactive compound, the photoactive compound being a combination of a photopolymerization initiator and a polymerizable reactive compound capable of radical polymerization or cationic polymerization (Patent Literatures 1-4).

When recording holograms, if there is a recording layer made of photopolymer in an area where interference patterns are formed by intersection of reference light and object light, a photopolymerization initiator causes a chemical reaction and becomes an active substance in the area of high light intensity among the interference patterns. This then acts on the polymerizable compound, causing it to polymerize. In this process, when there is a difference in refractive index between a matrix resin and a polymer generated from the polymerizable compound, the interference patterns are fixed in the recording layer as a difference in refractive index. In addition, when the polymerizable compound polymerizes, diffusion of the polymerizable compound occurs from a periphery thereof, causing a concentration distribution of the polymerizable compound or its polymerized product inside the recording layer. Based on this principle, an interference pattern is recorded on the holographic recording medium as a refractive index difference.

Hereinafter, the process of changing the optical characteristics of the recording layer by exposing the recording layer of the medium under predetermined conditions as described above will be referred to as “recording exposure”. The process of recording and exposing different interference patterns at the same position by changing the intersection angle between the reference light and the object light or by changing their respective angles of incidence will be referred to as “multiple recording exposure”. The number of times which multiple recording exposure is performed will be referred to as “total multiplex number”. Therefore, recording exposure such as shift multiplexing, in which recording exposure is performed at a slightly shifted position rather than at the same position, is not included in the multiplex recording exposure of this application.

On the other hand, when reproducing data, only a reproduction light is used, and the irradiated reproduction light causes diffraction according to the interference patterns. At this time, even if the wavelength of the reproduction light does not match the wavelength of the recording light, diffraction will occur if the interference patterns and the Bragg condition are satisfied. Therefore, if corresponding interference patterns are recorded according to the wavelength and incidence angle of the reproduction light to be diffracted, it is possible to cause the reproduction light in a wide wavelength range to be diffracted. For example, in AR glasses, the display color gamut can be widened. Here, the value obtained by dividing the intensity of the diffraction light by the intensity of the reproduction light is referred to as “diffraction efficiency”. In AR glasses, the diffraction efficiency is correlated with the brightness of the displayed AR layer.

However, when multiple recording exposure is performed with high diffraction efficiency and a large total number of multiplexes, in which recording is performed by changing the angle of incidence of the recording light onto the holographic recording medium, an unwanted diffraction phenomenon called “holographic scattering” can occur. In this case, it is known that inappropriate multiple recording exposure causes holographic scattering of particularly high intensity (Patent Literature 5). When this holographic scattering is strong, the reconstructed light and the diffracted light are scattered, causing not only a significant decrease in the diffraction efficiency but also the noise light being added to the AR image. According to the study by the present inventors, it was found that this holographic scattering becomes particularly strong when An is 0.02 or more.

### CITATION LIST

### Patent Literature

[PTL 1] JP 2021-12249 A
[PTL 2] JP 2007-34334 A
[PTL 3] JP H8-160842 A
[PTL 4] JP 2003-156992 A
[PTL 5] JP 2019-053127 A

### SUMMARY OF INVENTION

### Technical Problem

An object of the present invention is to provide an optical element having sufficiently small holographic scattering when multiple recording exposure is performed.

### Solution to Problem

The present inventors have discovered that it is possible to produce an optical element having sufficiently small holographic scattering by performing multiple recording exposure so that the average exposure intensity is equal to or more than a specific value.

The gist of the present invention is as follows.

[1] A method for producing an optical element, wherein a hologram recording medium having a recording layer containing a polymerizable compound and a photopolymerization initiator is subjected to multiple recording exposure of a hologram under conditions where average exposure intensity based on the following formula (1) is 6 mW/cm² or more.

$$[ Math . 1 ]$$

$$Average exposure intensity = \frac{{\sum }_{i = 1}^{m} ( {ET}_{i} \times {EPW}_{i} )}{{\sum }_{i = 1}^{m} ( {ET}_{i} + {EIT}_{i - 1} )} \qquad ( 1 )$$

(In the formula (1), ETᵢ is a single exposure time, which indicates exposure time (seconds) per multiple recording exposure. EPWᵢ is exposure light intensity, which indicates total light intensity (mW/cm²) of reference light and object light. EITi-1 is exposure interval time, which indicates time (seconds) between one recording exposure and another recording exposure in the multiple recording exposure. m is a natural number indicating a total number of multiplexes. With the proviso that, when i=1, EITi-1 is treated as zero.)

[2] The method for producing an optical element according to [1], wherein Δn of the hologram recording medium subjected to multiple recording exposure is 0.02 or more.

[3] The method for producing an optical element according to [1] or [2], wherein a thickness of the recording layer is 0.1 mm or more.

[4] The method for producing an optical element according to any one of [1] to [3], wherein EPWᵢ in the formula (1) is 10 mW/cm² or more.

[5] The method for producing an optical element according to any one of [1] to [4], wherein m in the formula (1) is 100 or more.

[6] The method for producing an optical element according to any one of [1] to [5], wherein EITi-1 in the formula (1) is 0.2 seconds or more.

### Advantageous Effects of Invention

According to the present invention, it is possible to produce an optical element that has sufficiently small holographic scattering when multiple recording exposure is performed.

### BRIEF DESCRIPTION OF DRAWINGS

FIG. 1 is a schematic diagram showing an example of a holographic recording device.

FIG. 2 is a schematic diagram showing an example of a device for measuring holographic scattering intensity.

### DESCRIPTION OF EMBODIMENTS

Hereinafter, embodiments of the method for producing an optical element of the present invention will be described in detail. The following description is an example (representative example) of an embodiment of the present invention. The present invention is not limited to these contents unless it goes beyond the gist thereof.

(Method for Producing Optical Element of the Present Invention)

The present invention relates to a method for producing an optical element by performing multiple recording exposure of an interference pattern by a reference light and an object light on the recording layer of a hologram recording medium.

This multiple recording exposure can be performed by rotating a holographic recording medium (hereinafter sometimes simply referred to as “medium”) having a recording layer containing a polymerizable compound and a photopolymerization initiator, by repeatedly recording and exposing interference patterns based on each angle of incidence at the same area of the holographic recording medium based on preset conditions, for example, so that the angles of incidence of the reference light and the object light are changed.

In the present invention, multiple recording exposure is performed under conditions where the average exposure intensity based on the following formula (1) is 6 mW/cm² or more.

$$[ Math . 1 ]$$

$$Average exposure intensity = \frac{{\sum }_{i = 1}^{m} ( {ET}_{i} \times {EPW}_{i} )}{{\sum }_{i = 1}^{m} ( {ET}_{i} + {EIT}_{i - 1} )} \qquad ( 1 )$$

(In the formula (1), ETᵢ is a single exposure time, which indicates exposure time (seconds) per multiple recording exposure. EPWᵢ is exposure light intensity, which indicates total light intensity (mW/cm²) of reference light and object light. EITᵢ₋₁ is exposure interval time, which indicates time (seconds) between one recording exposure and another recording exposure in the multiple recording exposure. m is a natural number indicating a total number of multiplexes. With the proviso that, when i=1, EITᵢ₋₁ is treated as zero.)

In the present invention, “recording exposure” refers to exposing a recording medium with an exposure intensity of 5 mW/cm² or more in the total of the reference light and the object light.

In the present invention, “pretreatment exposure” refers to exposure that is carried out such that the interval between the end of pretreatment exposure and the start of multiple recording exposure is 4 seconds or more as a reaction waiting time, since the pretreatment exposure is performed for the purpose of deactivating the polymerization inhibitor and oxygen contained in the recording layer of the medium.

In the present invention, “post exposure” refers to exposure performed with an interval of 4 seconds or more from the end of multiple recording exposure in order to wait sufficiently for the reaction of the last recording in the multiple recording exposure.

In the present invention, the reference light is the light that serves as a reference when recording an interference pattern on a medium, and is irradiated to this recording layer by overlapping an object light when exposing the recording layer of the medium.

In the present invention, the object light is the light irradiated to the recording layer of the medium in order to record holograms in the medium with interference fringes corresponding to the interference with the reference light according to the wavelength and diffraction of the reproduction light required as an optical element used for AR glasses and the like.

The light source that can be used for recording exposure in the present invention can be arbitrarily selected in the absorption wavelength region of the photopolymerization initiator in the recording layer of the medium. Particularly suitable light sources include, for example, lasers with excellent monochromaticity and directivity such as: solid lasers such as ruby, glass, Nd-YAG, Nd-YVO₄ lasers; diode lasers such as GaAs, InGaAs, and GaN lasers; gas lasers such as helium-neon, argon, krypton, excimer, and CO₂ lasers; and dye lasers including dyes.

The wavelength of the light for recording exposure in the present invention may be in the absorption wavelength region of the photopolymerization initiator in the recording layer, and can be arbitrarily selected from the ultraviolet region to the visible region. The wavelength of the light for recording exposure is preferably 300 nm or more, and more preferably 350 nm or more, and preferably 600 nm or less, and more preferably 450 nm or less.

In the present invention, the average exposure intensity refers to the average exposure intensity for the total number of multiplexes of the hologram multiplex recording exposure calculated by the above formula (1). The smaller this average exposure intensity is, the greater the holographic scattering intensity is. For this reason, the average exposure intensity is 6 mW/cm² or more, preferably 7 mW/cm² or more, and even more preferably 8 mW/cm² or more. On the other hand, when the average exposure intensity is too high, it becomes difficult to control the operation of the device. Threfore, it is not suitable for stable production. For this reason, the average exposure intensity is preferably 90 mW/cm² or less, more preferably 70 mW/cm² or less, and even more preferably 50 mW/cm² or less.

In the formula (1), the single exposure time ETᵢ is the exposure time (seconds) per multiple recording exposure. The single exposure time ETᵢ can be selected appropriately. The single exposure time ETᵢ does not need to be the same for all multiple recordings, and may be different. For example, the single exposure time ETᵢ can be increased exponentially according to the prediction of the remaining amount of the polymerizable compound and the photopolymerization initiator consumed by the photopolymerization reaction. The single exposure time ETᵢ is not particularly limited, but since it tends to enable recording exposure with higher accuracy, it is preferably 3×10−3 seconds or more, more preferably 2×10-2 seconds or more, and even more preferably 0.1 seconds or more. On the other hand, when the recording exposure time ETᵢ is too long, the hologram recording tends to be hindered by deterioration of the light coherence due to air fluctuations during exposure. For this reason, the single exposure time ETᵢ is preferably 100 seconds or less, and more preferably 50 seconds or less.

In the formula (1), the exposure light intensity EPWᵢ is the total light intensity of the object light and the reference light used for recording exposure. When the exposure light intensity EPWᵢ is low, the single exposure time ETᵢ for irradiating sufficient exposure energy becomes long. For this reason, in consideration of the producing takt time of the optical element, the exposure light intensity EPWᵢ is preferably 10 mW/cm² or more, more preferably 20 mW/cm² or more, and even more preferably 30 mW/cm² or more. On the other hand, when the exposure light intensity EPWᵢ is too large, stable production becomes difficult due to control problems caused by fluctuations in the light source intensity. For this reason, the exposure light intensity EPWᵢ is preferably 1 W/cm² or less, and more preferably 500 mW/cm² or less. In consideration of forming interference fringes suitable for recording, the ratio of the light intensities of the object light and the reference light is generally 1:1, but there is no particular limitation, and it can be changed appropriately even during multiple recording exposure.

In the formula (1), the exposure interval time EITᵢ₋₁ is the time between one recording exposure and another recording exposure (with the proviso that, when i=1, EITᵢ₋₁ is treated as zero). The exposure interval time EITᵢ₋₁ can be changed as appropriate even during multiple recording exposure, but when it is too short, the vibration of the device that performs the multiple recording exposure dose not have enough time to settle, interference fringes will not be properly irradiated onto the medium, and diffraction efficiency will not be recorded. For this reason, the exposure interval time EITᵢ₋₁ is preferably 0.2 seconds or more, and more preferably 0.3 seconds or more. On the other hand, when the exposure interval time EITᵢ₋₁ is long, the average exposure intensity will be small, which will deteriorate the holographic scattering intensity. For this reason, the exposure interval time EITᵢ₋₁ is preferably 2 seconds or less, more preferably 1.5 seconds or less, and even more preferably 1 second or less.

When the total number of multiplexes m of the multiple recording exposure is small, it is difficult to obtain an AR image having a wide display color gamut from the obtained optical element, and it is not suitable for practical use. Therefore, the total number of multiplexes m is preferably 100 or more, and more preferably 150 or more. On the other hand, the larger the total number of multiplexes m, the wider the display color gamut will be and the higher the color reproducibility of the AR image will be, as described above, but the longer the time required for multiple recording exposure will be, and the lower the producing efficiency of the optical element will tend to be. Therefore, the total number of multiplexes m is preferably 600 or less, and more preferably 400 or less.

In the present invention, when controlling the exposure time, the recording exposure time can be controlled by using a shutter that physically blocks light, a liquid crystal shutter that uses light-dark inversion of liquid crystal, or the like.

When producing an optical element according to the present invention, a pretreatment exposure may be performed on the medium before multiple recording exposure in order to prevent exposure inhibition, thereby deactivating a polymerization inhibitor and oxygen contained in the recording layer of the medium.

When producing an optical element according to the present invention, a post exposure may be performed on the medium after multiple recording exposure in order to fix the interference pattern to the optical element, thereby stabilizing an unreacted polymerizable compound and a photopolymerization initiator in the recording layer.

Light sources used for this pretreatment exposure and post exposure include LEDs, UV lamps, xenon lamps, mercury lamps, and the like. This light source can be selected arbitrarily as long as it can irradiate light in the absorption wavelength region of the photopolymerization initiator in the recording layer, and the same laser as for recording exposure can also be used.

The diffraction efficiency of the optical element produced according to the present invention (hereinafter sometimes referred to as the “optical element of the present invention”) can be determined by irradiating the optical element with a reference light as a reproduction light.

The diffraction efficiency ηᵢ from the i-th recorded and exposed hologram can be determined from the relationship between the diffracted light intensity Idi obtained from the recorded interference pattern and the transmitted light intensity Iₜᵢ of the reproduction light. The diffraction efficiency ηᵢ is defined by the following formula (2).

$$[ Math . 3 ]$$

$${η}_{i} = \frac{{I}_{di}}{{I}_{di} + {I}_{ti}} \qquad ( 2 )$$

For example, when the optical element of the present invention is applied to a light guide plate of AR glass, since a bright AR image tends to be obtained, the average diffraction efficiency of each hologram exposed for multiple recording is preferably 0.2 or more, more preferably 0.3 or more, and even more preferably 0.4 or more. On the other hand, when the diffraction efficiency of the hologram is too high, a large amount of polymerizable compound is consumed in each recording exposure, making it difficult to record with a large total multiplex number. For this reason, the average diffraction efficiency is preferably 0.9 or less, and more preferably 0.8 or less.

In the present invention, An shown in the following formula (3) is used as an evaluation index for the optical element exposed for multiple recording. The larger this An is, the more holograms can be multiplex recorded with high diffraction efficiency. An is preferably 0.02 or more, more preferably 0.025 or more, and even more preferably 0.03 or more, since sufficient brightness and wide color display performance are given to a light guide plate of AR glass. Due to the principle of photopolymer materials, an excessively large An rather causes strong scattering in the medium. For this reason, An is preferably 0.1 or less, and more preferably 0.8 or less.

$$[ Math . 4 ]$$

$$Δ n = \frac{λ \cdot cos θ}{π \cdot T} {\sum }_{i = 1}^{m} \sqrt{{sin}^{- 1} {η}_{i}} \qquad ( 3 )$$

(In the formula, m is the total multiplex number. ηᵢ is the diffraction efficiency of the hologram exposed for multiplex recording at the i-th time. A is the wavelength of the light source used for multiplex recording. 0 is the angle between the object light and the reference light. T is the thickness of the hologram recording material.)

(Components of Medium in the Present Invention)

The hologram recording medium used in the present invention has a recording layer containing at least a polymerizable compound and a photopolymerization initiator. A preferable example of the composition for forming such a recording layer (hereinafter also referred to as a “recording layer forming composition”) includes a photopolymer containing in an appropriate matrix resin, a polymerizable compound capable of radical polymerization or cationic polymerization as a polymerizable compound, a photopolymerization initiator that promotes the polymerization of the polymerizable compound, and a polymerization inhibitor which is a substance that inhibits the polymerization of the polymerizable compound. The recording layer forming composition may further contain a radical scavenger.

The medium in the present invention has a recording layer and, if necessary, a support and other layers. Usually, the medium has a support, and the recording layer and other layers are laminated on this support to constitute the medium. However, when the recording layer and other layers have the strength and durability required for the medium, the medium may not have a support. Examples of other layers include a protective layer, a reflective layer, an anti-reflective layer (anti-reflective film), and the like.

<About recording layer forming composition>

The recording layer of the medium according to the present invention is formed from a recording layer forming composition described in detail below. Here, the matrix resin is usually made to exist in the recording layer as a crosslinked network structure by filling the recording layer forming composition between the flat substrates and then polymerizing or crosslinking the composition. Therefore, the matrix resin will be contained in the recording layer forming composition in the form of a composition for forming a matrix resin by polymerization or cross-linking.

That is, the recording layer forming composition according to the present invention can contain a polymerizable compound, a composition for forming a matrix resin, a photopolymerization initiator, a polymerization inhibitor, and optionally a radical scavenger.

The components of the composition for forming the hologram recording layer are described in detail below.

<<About polymerizable compounds>>

The polymerizable compound according to the present invention is a compound that can be polymerized using the photopolymerization initiator described later. No particular limitation is imposed on the type of polymerizable compound, and an appropriate compound can be selected from known compounds. Examples of the polymerizable compound include cationically polymerizable monomers, anionically polymerizable monomers, and radically polymerizable monomers.

Any of these compounds can be used, and two or more of them may be used in combination.

Examples of the cationically polymerizable monomer include epoxy compounds, oxetane compounds, oxolane compounds, cyclic acetal compounds, cyclic lactone compounds, thiirane compounds, thietane compounds, vinyl ether compounds, spiro orthoester compounds, ethylenically unsaturated compounds, cyclic ether compounds, cyclic thioether compounds, vinyl compounds, and the like.

Any one of these cationically polymerizable monomers may be used alone, or any combination of two or more of them may be used at any ratio.

Examples of the anionically polymerizable monomer include hydrocarbon monomers, polar monomers, and the like.

Examples of the hydrocarbon monomers include styrene, x-methylstyrene, butadiene, isoprene, vinylpyridine, vinylanthracene, derivatives thereof, and the like.

Examples of the polar monomers including methacrylic acid esters, acrylic acid esters, vinyl ketones, isopropenyl ketones, other polar monomers, and the like.

Any one of these anionically polymerizable monomers may be used alone, or any combination of two or more of them may be used at any ratio.

Examples of the radically polymerizable monomer include (meth) acryloyl group-containing compounds, (meth) acrylamides, vinyl esters, vinyl compounds, styrenes, spiro ring-containing compounds, and the like.

Any of these radically polymerizable monomers may be used alone, or any combination of two or more of them may be used at any ratio.

In this specification, methacryl and acrylic are collectively referred to as (meth) acrylic, and methacryloyl and acryloyl are collectively referred to as (meth) acryloyl.

Among the above compounds, (meth) acryloyl group-containing compounds are preferred in terms of steric hindrance during radical polymerization.

Among the above polymerizable compounds, compounds having a halogen atom (iodine, chlorine, bromine, and the like) or a hetero atom (ηitrogen, sulfur, oxygen, and the like) in the molecule are preferred because they have a high refractive index. Among the above, those having a heterocyclic structure are preferable because they can obtain a higher refractive index.

<<About matrix resin and composition for forming matrix resin>>

The matrix resin according to the present invention refers to a cured product having a crosslinked network structure formed by a polymerization reaction or a crosslinking reaction. The composition for forming a matrix resin refers to a matrix resin precursor before bond formation by polymerization reaction and crosslinking reaction.

The matrix resin has a crosslinked network structure. This allows the matrix resin to stabilize the spatially uniform dispersion of the polymerizable compounds and photopolymerization initiator in the recording layer by appropriately preventing the mobility of the polymerizable compound and photopolymerization initiator. Further, the matrix resin prevents the diffusion of the polymer by intertwining with the polymer generated in the recording layer. The matrix resin prevents recorded information from being erased by preventing the diffusion of this polymer. Furthermore, since the matrix resin has a higher elastic modulus than in a liquid state, it plays a role of maintaining the physical shape of the recording layer.

The matrix resin forming composition is not restricted as long as it can maintain sufficient compatibility with the polymerizable compound, its polymer, and photopolymerization initiator even after bond formation by polymerization reaction or crosslinking reaction. The matrix resin forming composition preferably includes a compound having at least two or more functional groups selected from the group consisting of an isocyanate group, a hydroxyl group, a mercapto group, an epoxy group, an amino group, and a carboxy group in the molecule. These may be used alone or in combination of two or more.

The following examples (1) to (8) are examples to form a chemical bond that forms a crosslinked network structure by using one or more of these compounds in combination.
(1) Forming an isocyanurate bond through a reaction between compounds having isocyanate groups.
(2) Forming an urethane, a thiourethane, an urea, or an amide bonds by combining a compound having an isocyanate group and a compound having an active hydrogen in the molecule, such as compounds containing hydroxyl groups, mercapto groups, amino groups, or carboxy groups.
(3) Forming an ester bond by combining a compound having a hydroxyl group and a compound having a carboxy group.
(4) Forming an amide bond by combining a compound having an amino group and a compound having a carboxy group.
(5) Forming an ether bond through a reaction between compounds having epoxy groups.
(6) Forming an ether bond by combining an epoxy group and a hydroxyl group.
(7) Forming an amine bond by combining a compound having an epoxy group and a compound having an amino group.
(8) Forming multiple types of bonds by combining the above (1) to (7).

Among these, the combination of a compound having an isocyanate group and a compound having two or more hydroxyl groups in the molecule as an isocyanate-reactive functional group is preferable, because it provides a high degree of freedom in selecting the matrix resin structure and has no odor.

In this case, examples of compounds having an isocyanate group include isocyanic acid, butyl isocyanate, octyl isocyanate, butyl diisocyanate, hexyl diisocyanate (HMDI), isophorone diisocyanate (IPDI), 1,8-diisocyanato-4-(isocyanatomethyl) octane, 2,2, 4-and/or 2,4, 4-trimethylhexamethylene diisocyanate, isomeric bis (4,4′-isocyanatocyclohexyl) methanes and mixtures thereof having any desired isomer content, isocyanatomethyl-1,8-octanediisocyanate, 1,4-cyclohexylene diisocyanate, isomeric cyclohexanedimethylene diisocyanates, 1,4-phenylene diisocyanate, 2,4- or 2,6-toluene diisocyanate, 1,5-naphthylene diisocyanate, 2,4′- or 4,4′-diphenylmethane diisocyanate, triphenylmethane 4,4′, 4″-triisocyanate, and the like.

It is also possible to use an isocyanate derivative having a urethane structure, a urea structure, a carbodiimide structure, an acrylic urea structure, an isocyanurate structure, an allophanate structure, a biuret structure, an oxadiazinetrione structure, a uretdione structure, and/or an iminooxadiazinedione structure.

Any one of them may be used alone, or any combination of two or more of them may be used at any ratio.

Examples of compounds having two or more hydroxyl groups in the molecule as isocyanate-reactive functional groups include: glycols such as ethylene glycol, triethylene glycol, diethylene glycol, polyethylene glycol, propylene glycol, polypropylene glycol, neopentyl glycol, and the like; diols such as butanediol, pentanediol, hexanediol, heptanediol, tetramethylene glycol, and the like; bisphenols; triols such as glycerin, trimethylolpropane, butanetriol, pentanetriol, hexanetriol, decanetriol, and the like; compounds obtained by modifying these polyfunctional alcohols with a polyethyleneoxy chain or a polypropyleneoxy chain; polyfunctional polyoxybutylenes; polyfunctional polycaprolactones; polyfunctional polyesters; polyfunctional polycarbonates; polyfunctional polypropylene glycols, and the like.

Any one of them may be used alone, or any combination of two or more of them may be used at any ratio.

When forming a matrix resin, a combination of a compound having an epoxy group and a compound having an amino group includes a combination in which the reaction rate of bond formation in the matrix resin forming composition is relatively high. Therefore, in some cases, a matrix resin is formed as a bond-forming reaction progressing in a short time by leaving at room temperature.

On the other hand, a combination of a compound having an isocyanate group and a compound having a hydroxyl group, which has a high degree of freedom in selecting the matrix resin structure and is a preferable combination for forming a matrix resin, does not have a high reaction rate of bond formation, and the bond formation may not be completed and the matrix resin may not be formed even after standing at room temperature for several days. When using a composition for matrix resin formation with such a low reaction rate of bond formation, the bond formation reaction of the composition for matrix resin formation can be accelerated by heating, as in a general chemical reaction. Therefore, depending on the composition for forming the matrix resin, it is preferable to heat the recording layer forming composition between the two substrates for the formation of the matrix resin after filling the recording layer forming composition between the two substrates.

<<About Radical Scavengers>>

In holographic recording, the recording layer forming composition may contain a radical scavenger in order to accurately fix the interference light intensity pattern as a polymer distribution in the holographic recording medium. The radical scavenger preferably has both a functional group that captures radicals and a reactive group that is covalently fixed to the matrix resin. A stable ηitroxyl radical group can be mentioned as a functional group that captures radicals.

Examples of the reactive groups fixed to the matrix resin by covalent bonds include hydroxyl groups, amino groups, isocyanate groups, and thiol groups. Examples of the radical scavengers include 4-hydroxy-2,2,6,6-tetramethylpiperidine-1-oxyl free radical (TEMPOL), 3-hydroxy-9-azabicyclo[3.3.1]nonane N-oxyl, 3-hydroxy-8-azabicyclo[3.2.1] octane N-oxyl, and 5-HO-AZADO: 5-hydroxy-2-azabicyclo[3.3.1. 13,7]decane N-oxyl.

The various radical scavengers described above may be used alone or in combination of two or more in any combination and ratio.

### <<About Curing Catalysts>>

The bond formation reaction of the composition for forming the matrix resin can be promoted by using a suitable curing catalyst.

Examples of such curing catalysts include onium salts such as bis (4-t-butylphenyl) iodonium perfluoro-1-butanesulfonic acid, bis (4-t-butylphenyl) iodonium p-toluenesulfonic acid, and the like; Lewis acid-based catalysts such as zinc chloride, tin chloride, iron chloride, aluminum chloride, BF3 and the like; protic acids such as hydrochloric acid, phosphoric acid and the like; amines such as trimethylamine, triethylamine, triethylenediamine, dimethylbenzylamine, diazabicycloundecene, and the like; imidazoles such as 2-methylimidazole, 2-ethyl-4-methylimidazole, 1-cyanoethyl-2-undecylimidazolium trimellitate, and the like; bases such as sodium hydroxide, potassium hydroxide, potassium carbonate, and the like; tin catalysts such as dibutyltin laurate, dioctyltin laurate, dibutyltin octoate, and the like; bismuth catalysts such as tris (2-ethylhexanoate) bismuth, tribenzoyloxybismuth, bismuth triacetate, tris (dimethyldiocarbamic acid) bismuth, bismuth hydroxide, and the like.

Any one of these curing catalysts may be used alone, or two or more may be used in any combination and ratio.

### <<About Photopolymerization Initiators>>

The photopolymerization initiator according to the present invention refers to one that generates cations, anions, or radicals when irradiated with light. The photopolymerization initiator contributes to the polymerization of the above-described polymerizable compound. The type of photopolymerization initiator is not particularly limited, and can be appropriately selected depending on the type of polymerizable compound.

The cationic photopolymerization initiator used may be any known cationic photopolymerization initiator. Examples of the cationic photopolymerization initiator include aromatic onium salts. Specific examples of the aromatic onium salts include compounds containing an anionic component such as SbF6, BF4, ASF6, PF6, CF3SO3, or B (C6F5) 4″ and an aromatic cationic component containing an atom such as iodine, sulfur, ηitrogen, or phosphorus. Of these, diaryliodonium salts, triarylsulfonium salts, and the like are preferred.

Any one of the above exemplified cationic photopolymerization initiators may be used alone, or any combination of two or more of them may be used at any ratio.

The anionic photopolymerization initiator used may be any known anionic photopolymerization initiator. Examples of the anionic photopolymerization initiator include amines. Examples of the amines include: amino group-containing compounds such as dimethylbenzylamine, dimethylaminomethylphenol, 1,8-diazabicyclo [5.4. 0] undecene-7, and derivatives thereof; and imidazole compounds such as imidazole, 2-methylimidazole, 2-ethyl-4-methylimidazole, and derivatives thereof.

Any one of the above-exemplified anionic photopolymerization initiators may be used alone, or any combination of two or more of them may be used at any ratio.

The radical photopolymerization initiator used may be any known radical photopolymerization initiator. Examples of the radical photopolymerization initiator used include phosphine oxide compounds, azo compounds, azide compounds, organic peroxides, organic boronic acid salts, onium salts, bisimidazole derivatives, titanocene compounds, iodonium salts, organic thiol compounds, halogenated hydrocarbon derivatives and oxime ester compounds.

Any one of the above-exemplified radical photopolymerization initiators may be used alone, or any combination of two or more of them may be used at any ratio.

Other examples of photopolymerization initiators include imidazole derivatives, oxadiazole derivatives, naphthalene, perylene, pyrene, anthracene, coumarin, chrysene, p-bis(2-phenylethenyl) benzene and their derivatives, quinacridone derivatives, coumarin derivatives, aluminum complexes such as Al (CH (NO) 3, rubrene, perimidone derivatives, benzopyran derivatives, rhodamine derivatives, benzothioxanthene derivatives, azabenzothioxanthene, phenylpyridine complexes, porphyrin complexes, polyphenylene vinylene materials, and the like.

### <<About Polymerization Inhibitors>>

The polymerization inhibitor according to the present invention refers to a substance that inhibits the polymerization reaction of the polymerizable compound, and can be used as necessary. The polymerization inhibitor has the effect of inhibiting the progress of unexpected polymerization reactions such as those described below, and improving the storage stability of the medium before holographic recording. An example of the unexpected polymerization reaction is that, in the recording layer before holographic recording, a polymerization reaction of the polymerizable compound is initiated by radicals generated by the polymerization initiator and the polymerizable compound due to a slight amount of light or heat in the storage environment.

The type of polymerization inhibitor is not particularly limited as long as it can inhibit the polymerization reaction of the polymerizable compound. Specific examples of the polymerization inhibitor include phosphinates such as sodium phosphate sodium hypophosphite, and the like; mercaptans such as mercaptoacetic acid, mercaptopropionic acid, 2-propanethiol, 2-mercaptoethanol, thiophenol, and the like; aldehydes such as acetaldehyde, propionaldehyde, and the like; ketones such as acetone, methyl ethyl ketone, and the like; halogenated hydrocarbons such as trichlorethylene, perchlorethylene, and the like; terpenes such as terpinolene, x-terpinene, B-terpinene, γ-terpinene, and the like; non-conjugated dienes such as 1,4-cyclohexadiene, 1,4-cycloheptadiene, 1,4-cyclooctadiene, 1,4-heptadiene, 1,4-hexadiene, 2-methyl-1,4-pentadiene, 3,6-nonanedien-1-ol, 9,12-octadecadienol, and the like; linolenic acids such as linolenic acid, γ-linolenic acid, methyl linolenate, ethyl linolenate, isopropyl linolenate, linolenic anhydride, and the like; linoleic acids such as linoleic acid, methyl linoleate, ethyl linoleate, isopropyl linoleate, linoleic anhydride, and the like; eicosapentaenoic acids such as eicosapentaenoic acid ethyl eicosapentaenoate, and the like; docosahexaenoic acids such as docosahexaenoic acid, ethyl docosahexaenoate, and the like; phenol derivatives such as 2,6-di-t-butyl-p-cresol, p-methoxyphenol, diphenyl-p-benzoquinone, benzoquinone, hydroquinone, pyrogallol, resorcinol, phenanthraquinone, 2,5-torquinone, benzylaminophenol, p-dihydroxybenzene, 2,4,6-trimethylphenol, butylated hydroxytoluene, and the like; ηitrobenzene derivatives such as o-dinitrobenzene, p-dinitrobenzene, m-dinitrobenzene, and the like; N-phenyl-1-naphthylamine, N-phenyl-2-naphthylamine, cuperone, phenothiazine, tannic acid, p-ηitrosamine, chloranil, aniline, hindered aniline, iron (III) chloride, copper (II) chloride, triethylamine, hindered amine, ηitroxy radicals including 2,2,6,6-tetramethylpiperidine-1-oxyl, triphenylmethyl radical, oxygen, and the like.

These polymerization inhibitors may be used alone or in any combination and ratio of two or more.

### <<About Other Components>>

Other components contained in the recording layer forming composition include a solvent, a plasticizer, a dispersant, a leveling agent, an antifoaming agent, an adhesion promoter, a compatibilizer, a sensitizer, and the like. For these components, conventionally known materials may be used alone, or two or more of them may be used in any combination and ratio.

### <<About the Content of Each Component>>

The content of each component in the recording layer forming composition according to the present embodiment is arbitrary as long as it does not depart from the spirit of the present invention. The content of each component in the recording layer forming composition according to the present embodiment is preferably within the following range based on the total mass (100% by mass) of the composition.

The content of the total amount of matrix resin is usually 0.1% by mass or more, preferably 10% by mass or more, and more preferably 35% by mass or more. Further, it is usually 99.9% by mass or less, preferably 998 by mass or less, and more preferably 98% by mass or less. By setting the content of the matrix resin to the above lower limit or more, it becomes easy to form the recording layer.

The content of the curing catalyst used to promote matrix resin formation is preferably determined in consideration of the rate of bond formation of the matrix-forming components. The content of the catalyst is usually 5% by mass or less, preferably 4% by mass or less, and more preferably 1% by mass or less, and preferably 0.005% by mass or more.

The content of the polymerizable compound is usually 0.1% by mass or more, preferably 18 by mass or more, and more preferably 2% by mass or more. Further, it is usually 80% by mass or less, preferably 50% by mass or less, and more preferably 30% by mass or less. Sufficient diffraction efficiency can be obtained when the content of polymerizable compound is at least the above lower limit. The compatibility of the recording layer is maintained when the content of the polymerizable compound is equal to or less than the above upper limit.

The content of the radical scavenger is preferably 0.5 μmol/g or more, more preferably 1 μmol/g or more and 100 μmol/g or less, more preferably 50 μmol/g in molar amount per unit mass of the recording layer forming composition.

When the content of the radical scavenger is too small, the efficiency of capturing radicals is low, and the polymer with a low degree of polymerization tends to diffuse, and the components that do not contribute to the signal will tend to increase. On the other hand, when the content of the radical scavenger is too high, the polymerization efficiency of the polymer will be decreased, and it tends to be impossible to record signals. When two or more radical scavengers are used in combination, it is preferable that the total amount of the radical scavengers satisfies the above range.

The content of the photopolymerization initiator is usually 0.1% by mass or more, preferably 0.3% by mass or more, and usually 20% by mass or less, preferably 18% by mass or less, more preferably 168 by mass or less. When the content of the photopolymerization initiator is equal to or more than the above lower limit, sufficient recording sensitivity can be obtained. On the other hand, when the content of the photopolymerization initiator is equal to or less than the above upper limit, a decrease in sensitivity due to excessive radical generation can be suppressed.

The content of the polymerization inhibitor is usually 0.001% by mass or more, and preferably 0.005% by mass or more. Further, it is usually 30% by mass or less, and preferably 10% by mass or less. When the content of the polymerization inhibitor is within the above range, it is possible to inhibit the progress of unexpected polymerization reactions initiated by radicals generated by slight light or heat.

The total content of other components is usually 30% by mass or less, preferably 15% by mass or less, and more preferably 5% by mass or less.

### <About the Thickness of the Recording Layer>

The thickness of the recording layer in the present invention is preferably 0.1 mm or more and 3.0 mm or less, more preferably 0.3 mm or more and 2 mm or less. When the thickness of the recording layer is within this range, the selectivity of each hologram becomes high during multiplex recording on the holographic recording medium, and the degree of multiplex recording tends to be high.

Furthermore, the light transmittance of the recording layer at the recording light wavelength can be maintained high, and it becomes possible to record uniformly over the entire recording layer in the thickness direction, which tends to make it possible to realize multiple recording with a high S/N ratio.

### <Support>

No particular limitation is imposed on the details of the support so long as it has the strength and durability required for the medium, and any support can be used.

No limitation is imposed on the shape of the support, and the support is generally formed into a flat plate or a film.

No limitation is imposed on the material forming the support, and the material may be transparent or may be opaque.

Examples of the material for the transparent support include organic materials such as acrylic, polyethylene terephthalate, polyethylene naphthoate, polycarbonate, polyethylene, polypropylene, amorphous polyolefin, polystyrene, and cellulose acetate; and inorganic materials such as glass, silicon, and quartz. Of these, polycarbonate, acrylic, polyester, amorphous polyolefin, glass, and the like are preferred, and polycarbonate, acrylic, amorphous polyolefin, and glass are more preferred.

Examples of the material for the opaque support include metals such as aluminum; and a coating material obtained by coating the above-mentioned transparent support with a metal such as gold, silver, or aluminum, or a dielectric such as magnesium fluoride or zirconium oxide.

No particular limitation is imposed on the thickness of the support. Preferably, the thickness is in the range of generally 0.05 mm or more and 1 mm or less. When the thickness of the support is equal to or more than the above lower limit, the mechanical strength of the holographic recording medium can be ensured, and warpage of the substrate can be prevented. When the thickness of the support is equal to or less than the above upper limit, the transmission amount of light can be ensured, and an increase in cost can be prevented.

The surface of the support may be subjected to surface treatment. The surface treatment is generally performed in order to improve the adhesion between the support and the recording layer. Examples of the surface treatment include corona discharge treatment performed on the support and the formation of an undercoat layer on the support in advance. Examples of the composition for the undercoat layer include halogenated phenols, partially hydrolyzed vinyl chloride-vinyl acetate copolymers, and polyurethane resins.

The surface treatment on the support may be performed for a purpose other than the improvement in adhesion. Examples of such surface treatment include reflecting coating treatment in which a reflecting coating layer is formed using a metal material such as gold, silver, or aluminum; and dielectric coating treatment in which a dielectric layer formed of magnesium fluoride, zirconium oxide, and the like. Such a layer may be formed as a single layer, or two or more layers may be formed.

The surface treatment on the support may be performed for the purpose of controlling the gas and water permeability of the substrate. For example, when the support supporting the recording layer has the function of preventing permeation of gas and water, the reliability of the medium can be further improved.

The support may be disposed only on one of the upper and lower sides of the recording layer of the holographic recording medium of the present invention or may be disposed on both sides. When supports are disposed on both the upper and lower sides of the recording layer, at least one of the supports is made transparent so that it can transmit active energy rays (such as excitation light, reference light, and reproduction light).

When the holographic recording medium has the support on one side or both sides of the recording layer, a transmission hologram or a reflection hologram can be recorded. When a support having reflection characteristics is used on one side of the recording layer, a reflection hologram can be recorded.

### <Protective Layer>

The protective layer is a layer for preventing influences of a reduction in the sensitivity of the recording layer and deterioration in its storage stability due to oxygen or moisture. No limitation is imposed on the specific structure of the protective layer, and any known protective layer can be used. For example, a layer formed of a water-soluble polymer, an organic or inorganic material, and the like can be formed as the protective layer.

No particular limitation is imposed on the formation position of the protective layer. The protective layer may be formed, for example, on the surface of the recording layer or between the recording layer and the support. The protective layer may be formed on the outer surface side of the support. The protective layer may be formed between the support and another layer.

### <Reflective Layer>

The reflective layer is formed when the medium is formed as the reflection type holographic recording medium. In the reflection type holographic recording medium, the reflective layer may be formed between the support and the recording layer or may be formed on the outer side of the support. Generally, it is preferable that the reflective layer is present between the support and the recording layer.

Any known reflective layer may be used. For example, a thin metal film may be used.

### <Anti-Reflective Film>

When configuring the medium of the present invention as either a transmission type or a reflection type holographic recording medium, an anti-reflective film may be disposed on the side where object light and reading light are incident and emitted or between the recording layer and the support. The anti-reflective film improves the efficiency of utilization of light and prevents the occurrence of a ghost image.

Any known anti-reflective film may be used.

### <Method of Producing Recording Layer Forming Composition>

The method of producing a recording layer forming composition layer containing a polymerizable compound, a matrix resin, a photopolymerization initiator, and the like is not particularly limited, and the order of mixing can be adjusted as appropriate. In addition, when the recording layer forming composition contains components other than those described above, the components may be mixed in any combination and order.

When an isocyanate (a compound having an isocyanate group) and a polyol (a compound having two or more hydroxyl groups in the molecule) are used as the matrix resin, the recording layer forming composition can be obtained, for example, by the following method. However, the present invention is not limited thereto.

The polymerizable polymer, the photopolymerization initiator, and components other than the isocyanate and the urethane polymerization catalyst are mixed together to prepare a photoreactive composition (solution A). A mixture of the isocyanate and the urethane polymerization catalyst is prepared as solution B.

Alternatively, the polymerizable polymer, the photopolymerization initiator, and components other than the isocyanate may be mixed to prepare a photoreactive composition (solution A).

Preferably, each solution is subjected to dewatering and degassing. When the dewatering and degassing are insufficient, air bubbles are generated during the production of a holographic recording medium, and therefore a uniform recording layer may not be obtained. The dewatering and degassing may be performed by heating under reduced pressure so long as the components are not damaged.

Preferably, the recording layer forming composition including a mixture of the solution A and solution B is produced immediately before molding of the holographic recording medium. In this case, a mixing technique using a conventional method may be used.

When the solution A and the solution B are mixed, degassing may be optionally performed in order to remove residual gas.

Preferably, the solution A and the solution B are subjected to a filtration process separately or simultaneously after mixing in order to remove foreign substances and impurities. It is more preferable to filter these solutions separately.

The isocyanate used for the matrix resin may be an isocyanate-functional prepolymer prepared by a reaction of an isocyanate having an excessive amount of isocyanate groups with the polyol. The polyol used for the matrix resin may be an isocyanate reactive prepolymer prepared by a reaction of a polyol containing an excessive amount of isocyanate reactive functional groups with the isocyanate.

### <Method of Producing Medium>

No limitation is imposed on the method for producing the medium in the present invention. For example, the medium can be produced by coating the support with the above mentioned recording layer forming composition without using a solvent to form the recording layer.

Any known coating method can be used as the method of coating the recording layer forming composition. Specific examples of the coating method include a spray method, a spin coating method, a wire bar method, a dipping method, an air knife coating method, a roll coating method, a blade coating method, and a doctor roll coating method.

When a recording layer with a large thickness is formed, a method in which the recording layer forming composition is molded using a die, a method in which the recording layer forming composition is applied to a release film and punched with a die, and the like may be used to form the recording layer.

The holographic recording medium may be produced by mixing the recording layer forming composition with a solvent or an additive to prepare a coating solution, coating the support with the coating solution, and then drying the coating solution to form the recording layer. As also in this case, any coating method can be used. For example, any of the above described methods can be used.

No limitation is imposed on the solvent used for the above mentioned coating solution. It is generally preferable to use a solvent that can dissolve the component used sufficiently, provides good coating properties, and does not damage the support such as a resin substrate.

Examples of the solvent include: ketone-based solvents such as acetone, methyl ethyl ketone, and the like; aromatic-based solvents such as toluene, xylene, and the like; alcohol-based solvents such as methanol, ethanol, and the like; ketone alcohol-based solvents such as diacetone alcohol, and the like; ether-based solvents such as tetrahydrofuran, and the like; halogen-based solvents such as dichloromethane, chloroform, and the like; cellosolve-based solvents such as methyl cellosolve, ethyl cellosolve, and the like; propylene glycol-based solvents such as propylene glycol monomethyl ether, propylene glycol monoethyl ether, and the like; ester-based solvents such as ethyl acetate, methyl 3-methoxypropionate, and the like; perfluoroalkyl alcohol-based solvents such as tetrafluoropropanol, and the like; highly polar solvents such as dimethylformamide, dimethyl sulfoxide, and the like; chain hydrocarbon-based solvents such as n-hexane, and the like; cyclic hydrocarbon-based solvents such as cyclohexane, cyclooctane, and the like; and mixtures of these solvents.

One solvent may be used alone, or any combination of two or more solvents may be used at any ratio.

No limitation is imposed on the amount of the solvent used. However, from the viewpoints of coating efficiency and handleability, it is preferable to prepare a coating solution having a solid concentration of about 1 to 100% by mass.

When the resin matrix of the recording layer forming composition is thermoplastic, the recording layer forming composition can be molded by, for example, injection molding, sheet molding, or hot pressing to form a recording layer.

When the resin matrix is photo-or thermosetting having a small amount of volatile components, the recording layer forming composition can be molded by, for example, reaction injection molding or liquid injection molding to form a recording layer. In this case, when the molded body has sufficient thickness, rigidity, strength, and the like, the molded body can be used as it is as a medium.

Examples of the production method include: a production method in which the recording layer is formed by coating the support with the recording layer forming composition fused by heat and cooling the recording layer forming composition to solidify the composition; a production method in which the recording layer is formed by coating the support with the recording layer forming composition in liquid form and subjecting the recording layer forming composition to thermal polymerization to cure the composition; a production method in which the recording layer is formed by coating the support with the recording layer forming composition in liquid form and subjecting the recording layer forming composition to photopolymerization to cure the composition; and the like.

The thus-produced medium can be in the form of a self-supporting slab or disk and can be used for three-dimensional image display devices, diffraction optical elements, large-capacity memories, and the like.

### EXAMPLES

The present invention will be described in more detail by way of Examples. The present invention is not limited to the Examples so long as the invention does not depart from the scope thereof.

### [Materials Used]

Raw materials of compositions used in the Examples, and Comparative Examples are as follows.

### (Isocyanate Group-Containing Compound)

DURANATE™ TSS-100: hexamethylene diisocyanate-based polyisocyanate (NCO 17.6%) (manufactured by Asahi Kasei Corporation)
TAKENATE 600: aliphatic diisocyanate (manufactured by Mitsui Chemicals, Inc.)

### (Isocyanate-Reactive Functional Group-Containing Compound)

PLACCEL PCL-205U: polycaprolactonediol (molecular weight 530, manufactured by Daicel Corporation)
PLACCEL PCL-305: polycaprolactonetriol (molecular weight 550, manufactured by Daicel Corporation).
PLACCEL PCL-204HGT: polycaprolactonediol (molecular weight 400, manufactured by Daicel Corporation)

### (Polymerizable Compound)

HLM201: 2-[[2,2-bis(4-dibenzothiophenylthiomethyl)-3-(4-dibenzothiophenylthio) propoxy] carbonylamino]ethyl acrylate
HLM 303:2-[[2,2-bis [(2-dibenzothiophen-4-ylphenyl) sulfanylmethyl]-3-(1,3-benzothiazo-2-ylsulfanylmethyl) propoxy] carbonylamino]ethyl acrylate

### (Photopolymerization Initiator)

HLI02: 1-(9-ethyl-6-cyclohexanoyl-9H-carbazol-3-yl)-1-(0-acetyloxime) methyl glutarate

### (Curing Catalyst)

Octylic acid solution of tris(2-ethylhexanoate) bismuth (active ingredient amount 56% by mass)

### (Radical Scavenger)

TEMPOL: 4-hydroxy-2,2,6,6-tetramethylpiperidine-1-oxyl free radical (manufactured by TOKYO CHEMICAL INDUSTRY CO., Ltd.)

### [Preparation of TEMPOL Masterbatch]

0.03 g of TEMPOL was dissolved in 2.97 g of DURANATE™ TSS-100. Next, 0.0003 g of an octylic acid solution of tris(2-ethylhexanoate) bismuth was dissolved in the above mixture, and the resulting mixture was stirred at 45° C. under reduced pressure to allow the mixture to react for 2 hours.

### [Preparation of Recording Layer Forming Composition and Producing of Holographic Recording Medium]

### <Medium 1>

0.7599 g of polymerizable compound HLM101, 0.0304 g of photopolymerization initiator HLI02, and 1.0411 g of TEMPOL masterbatch were dissolved in 2.8794 g of DURANATE™ TSS-100 to obtain solution A.

Separately, 1.795 g of PLAXEL PCL-205U and 1.795 g of PLAXEL PCL-305 were mixed (PLAXEL PCL-205U: PLAXEL PCL-305 =50:50 (mass ratio)), and 0.00023 g of an octylic acid solution of tris(2-ethylhexanoate) bismuth was dissolved therein to obtain solution B.

After degassing solution A for 2 hours under reduced pressure and degassing solution B for 2 hours under reduced pressure at 45° C., 2.5537 g of solution A and 1.9463 g of solution B were mixed with stirring.

Then the above mixed solution was poured onto a slide glass with 0.6 mm-thick spacer sheets placed on two opposite edges, and another slide glass was placed thereon. Clips were used to fix the edges, and heating was performed at 80° C. for 24 hours to produce Medium 1 as an evaluation sample. In this evaluation sample, a recording layer with a thickness of 0.6 mm was formed between the slide glasses used as covers.

### <Medium 2>

0.5952g of TAKENATE 600, 1.2315g of polymerizable compound HLM303, 0.0387g of photopolymerization initiator HLI02, and 1.4531g of TEMPOL masterbatch were dissolved in 1.9341g of DURANATE™ TSS-100 to obtain solution A. Separately, 3.6289g of PLAXEL PCL-204HGT and 0.4032g of PLAXEL PCL-305 were mixed (PLAXEL PCL-204HGT: PLAXEL PCL-305=90:10 (mass ratio)), and 0.00024g of an octylic acid solution of tris(2-ethylhexanoate) bismuth was dissolved therein to obtain solution B.

After degassing solution A for 2 hours under reduced pressure and degassing solution B for 2 hours under reduced pressure at 45° C., 3.2829 g of solution A and 2.5202 g of solution B were mixed with stirring.

Then the above mixed solution was poured onto a slide glass with 0.6 mm-thick spacer sheets placed on two opposite edges, and another slide glass was placed thereon. Clips were used to fix the edges, and heating was performed at 80° C. for 24 hours to produce Medium 2 an evaluation sample. In this evaluation sample, a recording layer having a thickness of 0.6 mm was formed between the slide glasses used as covers.

### [Producing of Optical Elements]

### <Holographic Recording Device>

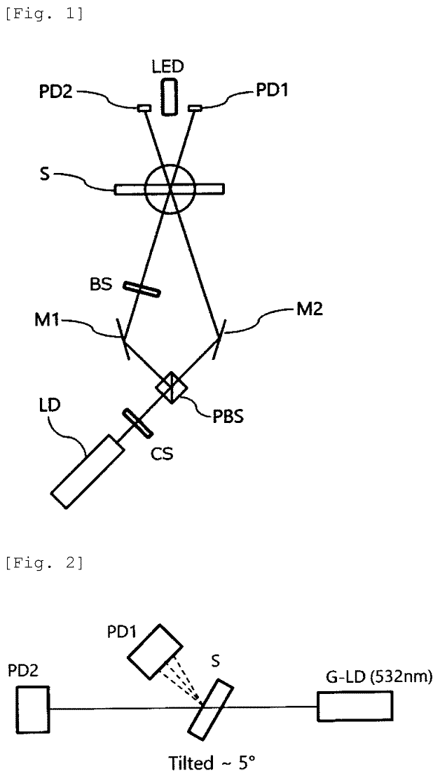

FIG. 1 is a structural diagram showing the outline of the device used for holographic recording on the medium.

In FIG. 1, S is a sample of the holographic recording medium (Medium 1 or Medium 2). Both M1 and M2 are mirrors. CS is an exposure time control shutter. BS is a beam shutter. PBS is a polarizing beam splitter. LED is a light source for post exposure (LED with a central wavelength of 405 nm manufactured by THORLAB). LD represents a recording laser light source emitting light with a wavelength of 405 nm (a single mode laser manufactured by TOPTICA Photonics and capable of emitting light with a wavelength of about 405 nm). PD1 and PD2 represent photodetectors.

### <Holographic Recording Exposure>

The light having a wavelength of 405 nm generated from the recording light laser light source LD was split using the polarizing beam splitter PBS, and these were regarded as object light (M1 side) and reference light (M2 side). And the two beams were irradiated so as to intersect on the recording surface at an angle of 59.3°. At this time, the light beam was split such that a bisector (hereinafter referred to as the optical axis) of the angle between the two beams was perpendicular to the recording surface of the holographic recording medium S, and the two beams obtained by splitting the light beam were applied such that the vibration planes of the electric field vectors of the two beams were perpendicular to a plane including the two intersecting beams.

The above case was assumed to be 0°, the beam shutter BS was opened, and the direction of the hologram recording medium S was changed to an angle of 24° while keeping the incident direction of the two beams fixed, and the exposure time control shutter CS was opened for 350 milliseconds as a pre-processing exposure, the object light and the reference light were irradiated, and the deactivation of oxygen acting as a radical quencher was waited in a dark state for 10 seconds. Thereafter, multiple recording exposure was performed under conditions that gave the average exposure intensity shown in Table 1, while changing the angle of the recording surface with respect to the optical axis by 0.2° each time. At this time, the total exposure energy was set to 2 J/cm² in all Examples and Comparative Examples so that the amounts of the polymerizable compound and the photopolymerization initiator consumed for recording were equal.

### <Post Exposure>

After the multiplex recording exposure, the rotation angle was returned to 0°, and the signal growth time of 120 seconds was waited in a dark state, and the recording was fixed by irradiating the sample with 4 J/cm² by the post exposure light source LED.

### <Reproduction of Hologram Recording >

The beam shutter BS in FIG. 1 was closed, and the recorded hologram was reproduced using the light on the mirror M2 side as the reference light. The light intensity detected by the photodetector PD1 was defined as the diffracted light Idi, and the light intensity detected by the photodetector PD2 was defined as the transmitted light Iₜᵢ. The diffraction efficiency ηᵢ of the light diffracted from each interference pattern was measured, and An was calculated using the above formulas (2) and (3). At this time, the diffraction due to the interference pattern during the pre-processing exposure was also reproduced in the same way, but it was not included in the multiplex number.

### <Measurement of Holographic Scattering Intensity>

FIG. 2 is a schematic diagram of a device for measuring holographic scattering intensity. S in FIG. 2 is the hologram recording medium after the above reproduction of hologram recording. G-LD (532 nm) is a laser light source for holographic scattering measurement (JUNO532 single mode laser manufactured by Showa Optronics Co., Ltd.) that can obtain a wavelength of 532 nm. PD1 and PD2 represent photodetectors.

The measurement light is incident on the sample S at an inclination such that the incident angle is approximately 5°. This angle of incidence is appropriately adjusted within the range of 5°+1° so that the holographic scattering light can enter the photodetector PD2 most intensely.

The holographic scattering intensity is evaluated as the ratio I_{H} (%) of the intensity of photodetector PD1 to the transmitted light intensity of photodetector PD2, calculated by the following formula (4).

$${I}_{H} = ( intensity of PD 1 / transmitted light intensity of PD 2 ) \times 100 \qquad ( 4 )$$

### <Evaluation Criteria>

The following evaluation criteria were set based on the holographic scattering intensity ratio I_{H}.
⊚: I_{H}≤0.15%
◯: 0.15%<I_{H}≤0.25%
x: 0.25%<I_{H}

### <Evaluation Results>

For Medium 1 and Medium 2, the parameters corresponding to the formula (1) were set so that the average exposure times was as shown in Table 1. The evaluation results of the holographic scattering intensity and Δn of the optical element obtained by multiple recording exposure are shown in Table 1.

| | | | Exposure | Exposure | | | | | | |
|---|---|---|---|---|---|---|---|---|---|---|
| | | Total | Interval | Light | Total | Total | Average | Holographic | | |
| | | Number of | Time | Intensity | Exposure | Recording | Exposure | Scattering | | |
| | Type of | Multiplexes | EITᵢ₋₁ | EPWᵢ | Energy | Time | Intensity | Intensity | | |
| | Medium | m | (second) | (mW/cm²) | (J/cm²) | (second) | (mW/cm²) | I_{H} (%) | Evaluation | Δ n |
| Example 1 | Medium 1 | 240 | 0.5 | 20 | 2 | 219 | 9.07 | 0.04 | ⊚ | 0.033 |
| Example 2 | Medium 1 | 240 | 0.7 | 40 | 2 | 217 | 9.12 | 0.06 | ⊚ | 0.034 |
| Example 3 | Medium 1 | 240 | 0.9 | 40 | 2 | 264 | 7.41 | 0.13 | ⊚ | 0.035 |
| Example 4 | Medium 1 | 240 | 0.35 | 20 | 2 | 183 | 10.84 | 0.03 | ⊚ | 0.033 |
| Example 5 | Medium 1 | 180 | 1 | 20 | 2 | 278 | 7.12 | 0.22 | ◯ | 0.036 |
| Example 6 | Medium 1 | 240 | 0.2 | 20 | 2 | 147 | 13.49 | 0.02 | ⊚ | 0.032 |
| Example 7 | Medium 2 | 180 | 1 | 20 | 2 | 279 | 7.18 | 0.18 | ◯ | 0.040 |
| Example 8 | Medium 2 | 240 | 0.75 | 20 | 2 | 279 | 7.17 | 0.13 | ⊚ | 0.044 |
| Example 9 | Medium 2 | 240 | 0.5 | 20 | 2 | 220 | 9.12 | 0.05 | ⊚ | 0.043 |
| Comparative | Medium 1 | 240 | 1 | 20 | 2 | 338 | 5.86 | 0.30 | X | 0.037 |
| Example 1 | | | | | | | | | | |
| Comparative | Medium 2 | 240 | 1 | 20 | 2 | 339 | 5.90 | 0.33 | X | 0.046 |
| Example 2 | | | | | | | | | | |

From Examples 1 to 6 and Comparative Example 1, it was confirmed that when multiple recording exposure was performed in Medium 1 so that the average exposure intensity based on the formula (1) was 6 mW/cm² or more, only the holographic scattering intensity was significantly reduced while maintaining a high An. When the average exposure intensity was 8 mW/cm² or more, a further decrease in the holographic scattering intensity was confirmed.

From Examples 7 to 9 and Comparative Example 2, it was confirmed that the holographic scattering intensity was also significantly reduced in Medium 2 when the average exposure intensity was 6 mW/cm² or more. When the average exposure intensity was 8 mW/cm² or more, a further decrease in the holographic scattering intensity was confirmed.

From these results, it can be seen that the method for producing an optical element of the present invention enables holographic recording with a sufficiently low holographic scattering intensity.

Although the present invention has been described in detail by way of the specific modes, it is apparent for those skilled in the art that various changes can be made without departing from the spirit and scope of the present invention.

The present application is based on Japanese Patent Application No. 2022-106251 filed on Jun. 30, 2022, the entire contents of which are incorporated herein by reference.

### INDUSTRIAL APPLICABILITY

The method for producing an optical element of the present invention is useful as a means for recording holograms having a sufficiently low holographic scattering intensity while maintaining Δn for expanding the display color gamut and obtaining a bright ΔR image, particularly in optical elements used in light guide plates for ΔR glasses, and the like.

### REFERENCE SIGNS LIST

<FIG. 1>
S Holographic recording medium
M1, M2 Mirror
LD Laser light source for recording light
PD1, PD2 Photodetector
LED LED light source for post exposure
BS Beam shutter
PBS Polarizing beam splitter
CS Exposure time control shutter

<FIG. 2>
S Holographic recording medium after multiple recording exposure
G-LD (532 nm) Laser light source for holographic scattering measurement
PD1, PD2 Photodetector

1. A method for producing an optical element, wherein a hologram recording medium having a recording layer containing a polymerizable compound and a photopolymerization initiator is subjected to multiple recording exposure of a hologram under conditions where average exposure intensity based on the following formula (1) is 6 mW/cm² or more.
$$[ Math . 1 ]$$
$$Average exposure intensity = \frac{{\sum }_{i = 1}^{m} ( {ET}_{i} \times {EPW}_{i} )}{{\sum }_{i = 1}^{m} ( {ET}_{i} + {EIT}_{i - 1} )} \qquad ( 1 )$$
(In the formula (1), ETᵢ is a single exposure time, which indicates exposure time (seconds) per multiple recording exposure. EPWᵢ is exposure light intensity, which indicates total light intensity (mW/cm²) of reference light and object light. EITᵢ₋₁ is exposure interval time, which indicates time (seconds) between one recording exposure and another recording exposure in the multiple recording exposure. m is a natural number indicating a total number of multiplexes. With the proviso that, when i=1, EITᵢ₋₁ is treated as zero.)

2. The method for producing an optical element according to claim 1, wherein Δn of the hologram recording medium subjected to multiple recording exposure is 0.02 or more.

3. The method for producing an optical element according to claim 1, wherein a thickness of the recording layer is 0.1 mm or more.

4. The method for producing an optical element according to claim 1, wherein EPWᵢ in the formula (1) is 10 mW/cm² or more.

5. The method for producing an optical element according to claim 1, wherein m in the formula (1) is 100 or more.

6. The method for producing an optical element according to claim 1, wherein EITᵢ₋₁ in the formula (1) is 0.2 seconds or more.
